(19) United States
(12) Patent Application Publication
(10) Pub. No.: US 2008/0291732 A1
(43) Pub. Date: Nov. 27, 2008

(54) Three cycle SONOS programming

(75) Inventor: Fredrick B. Jenne, Sunnyvale, CA (US)

Correspondence Address: CYPRESS/BLAKELY, BLAKELY SOKOLOFF TAYLOR & ZAFMAN, 1279 OAKMEAD PARKWAY, SUNNYVALE, CA, 94085-4040, US

(73) Assignee: Cypress Semiconductor Corporation

(21) Appl. No.: 11/904,143

(22) Filed: Sep. 25, 2007

Related U.S. Application Data
(60) Provisional application No. 60/931,700, filed on May 25, 2007.

(51) Int. Cl. G11C 16/06

(52) U.S. Cl. 365/185.18; 365/185.3

(57) ABSTRACT

A method to eliminate over-erase in a nonvolatile trapped-charge memory array during write operations includes a three-cycle process of bulk programming the memory array, bulk erasing the memory array and selectively inhibiting one or more memory cells in the memory array while applying a programming voltage to the memory array.

This application claims the benefit U.S. Provisional Patent Application No. 60/931,700, filed May 25, 2007.

### TECHNICAL FIELD

Embodiments of the present invention relate to nonvolatile, trapped-charge semiconductor memory and, in particular, to the programming of SONOS-type memory cells.

### BACKGROUND

SONOS (silicon-oxide-nitride-oxide-silicon) is a nonvolatile, trapped-charge semiconductor memory technology that provides several advantages over conventional floating-gate flash memories, including immunity from single point failures and programming at lower voltages. In contrast to floating-gate devices, which store charge on a conductive gate, SONOS devices trap charge in a dielectric layer. SONOS transistors are programmed and erased using a quantum mechanical effect known as Modified Fowler-Nordheim tunneling. A SONOS transistor is an insulated-gate field effect transistor (IGFET) with additional dielectric layers between a conventional control gate and a channel in the body or substrate of the transistor. The dielectric layers include a thin tunneling layer above the channel, a charge-trapping layer above the tunneling layer and a blocking layer between the charge-trapping layer and the control gate. A SONOS transistor can be fabricated as a P-type or N-type IGFET using CMOS (complementary metal-oxide-semiconductor) fabrications methods.

A SONOS transistor is programmed or erased by applying a voltage of the proper polarity, magnitude and duration between the control gate and the substrate. A positive gate-to-substrate voltage causes electrons to tunnel from the channel to charge charge-trapping dielectric layer and a negative gate-to-channel voltage causes holes to tunnel from the channel to the charge-trapping dielectric layer. In one case, the threshold voltage of the transistor is raised and in the other case, the threshold voltage of the transistor is lowered. The threshold voltage is the gate-to-source voltage that causes the transistor to conduct current when a voltage is applied between the drain and source terminals. For a given amount of trapped charge, the direction of the threshold voltage change depends on whether the transistor is an N-type or P-type FET. Absent any disturbances, the charge stored in the trapping layer has a very low leakage rate. The threshold voltages eventually decay to the intrinsic (uncharged) threshold voltage of the device, but normally the state of the transistor (ON or OFF) can be maintained and reliably read for years. The end-of-life data is usually defined by the time when the difference between the programmed threshold voltage and the erased threshold voltage drops below a minimum specified value (e.g., 0.5 volts).

FIG. 1 illustrates the change in threshold voltage V_{T} of an N-type SONOS transistor as a function of time for a programming voltage of +10 volts and an erase voltage of −10 volts. After approximately 10 milliseconds, the programmed threshold voltage is greater than +1 volt and the erased threshold is less than −1 volt. After a programming or erase operation is completed, the state of the transistor can be read by setting the gate-to-source voltage to zero, applying a small voltage between the drain and source terminals and sensing the current that flows through the transistor. In the programmed state, the N-type SONOS transistor will be OFF because the gate-to-source voltage will be below the programmed threshold voltage V_{TP}. In the erased state, the N-type SONOS transistor will be ON because the gate-to-source voltage will be above the erased threshold voltage V_{TE}. Conventionally, the ON state is associated with a logical “0⇄ and the OFF state is associated with a logical “1,” but the choice is arbitrary.

As illustrated in FIG. 1, the erase threshold voltage saturates if the duration of the erase pulsewidth exceeds a given time, T1 (approximately 10 milliseconds in the example shown in FIG. 1). This condition occurs because the hole injection current from the substrate into the memory layer and the back streaming of injected electron current from the gate into the memory layer are equal resulting in no net charge increase or decrease. In this state, the local electric field of the positive charge can induce hot electron back-streaming (e.g., from the gate side) that can damage the memory dielectric layers. The damage produces trapping sites in the memory dielectric layers that increases charge leakage (via trap assisted tunneling) and reduces the data retention. FIG. 1B illustrates the effect of over-erasing on data retention.

An over-erased condition can be reached via an accumulation of shorter erase pulses in a conventionally operated SONOS memory system. FIG. 2A illustrates two memory cells A and B in a row of a SONOS memory array, and their associated control lines. Each cell contains a SONOS memory transistor and a select transistor that is used when the cell is read. All of the transistors share a common substrate connection (SUB). The gates of the SONOS transistors (G_{A}, G_{B}) are connected to a SONOS word line (SWL). The source of the SONOS transistor in cell A is connected to a source line (SL0) and the source of the cell B SONOS transistor is connected to another source line (SL1). Conventionally, a write operation on a row in a SONOS array is conducted in two steps, or cycles, where a bulk erase (BE) operation is performed on all the cells in the row and then followed a program or inhibit operation on individual cells depending on the data that is being written. The bulk erase is accomplished (for N-type SONOS devices) by applying a negative pulse voltage V_{PN} on SWL, and a positive pulse voltage V_{PP} on SL0 and SL1 and the common substrate connection SUB, as illustrated in FIG. 2B. This has the effect of writing a “0” to every cell in the row. In the next step, the positive and negative voltages on the gates and substrate are reversed, as illustrated in FIG. 2C. The source connections of cells that are to be written to a “1” are also reversed so that the cells are exposed to the full voltage of the programming pulse. Cells that are to be written to a “0” are inhibited from programming (because they are already in a “0” state by virtue of the bulk erase) by the application of a positive inhibiting voltage V_{INH} on their source line connections. The inhibiting voltage reduces the electric field across the tunneling layer when the programming pulse is applied, reducing the tunneling of electrons to the charge trapping layer. FIG. 2C illustrates the voltage conditions for writing a “1” to cell A and inhibiting cell B.

This conventional, 2-cycle write operation can generate an over-erase condition in cells that are written to “0” on multiple consecutive writes, as illustrated in FIGS. 3A-3D. FIGS. 3A-3C illustrate the control waveforms for three consecutive writes where cell A is written to a “1” and cell B is written to “0.” FIG. 3D illustrates the threshold voltage VT_{B} of the SONOS transistor in cell B. From t0 to t1, VT_{B} transitions to an erased state from either a programmed or erased prior state. From t2 to t3, the cell is inhibited and threshold voltage increases only slightly. From t5 to t6, the cell is erased and VT_{B} is driven more negative. From t7 to t8, the cell is inhibited again with a slight increase in threshold voltage. From t9 to t10, the cell is erased again and driven into saturation. It can be seen that the sequence of bulk erase and write “0” can be repeated indefinitely, causing damage to the cell.

### BRIEF DESCRIPTION OF THE DRAWINGS

The present invention is illustrated by way of example and not limitation in the figures of the accompanying drawings, in which:

FIG. 1A illustrates over-erase in a SONOS memory.

FIG. 1B illustrates loss of data retention in an over-erased SONOS memory.

FIG. 2A illustrates a SONOS memory array;

FIG. 2B illustrates a bulk erase operation in a SONOS memory array;

FIG. 2C illustrates a write operation in a SONOS memory array;

FIGS. 3A-3C illustrates conventional 2-cycle programming control waveforms in a SONOS memory array;

FIG. 3D illustrates over-erased threshold voltages in a conventional 2-cycle SONOS memory array;

FIG. 4 illustrates a SONOS-type semiconductor device in one embodiment;

FIG. 5 illustrates bulk programming of a SONOS-type memory array in one embodiment;

FIGS. 6A-C illustrate 3-cycle programming control voltage waveforms in one embodiment;

FIG. 6D illustrates threshold voltage transitions in one embodiment of 3-cycle programming;

FIG. 7 is a flowchart illustrating a method for 3-cycle programming in one embodiment;

FIG. 8 is a graph illustrating data retention in a memory array in one embodiment; and

FIG. 9 is a block diagram illustrating a processing system in which embodiments of the invention may be implemented.

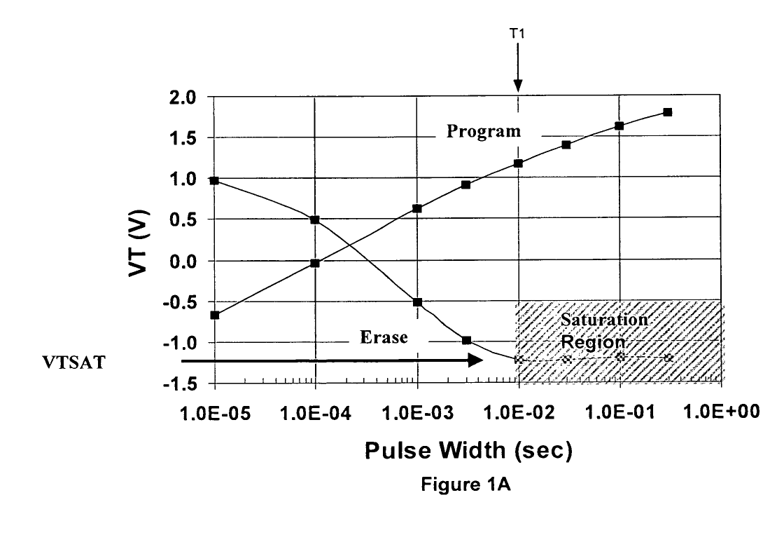

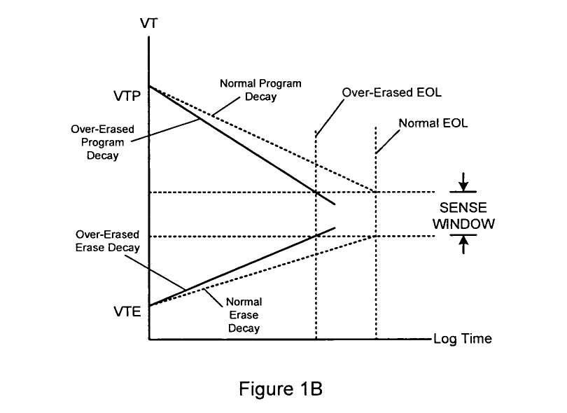

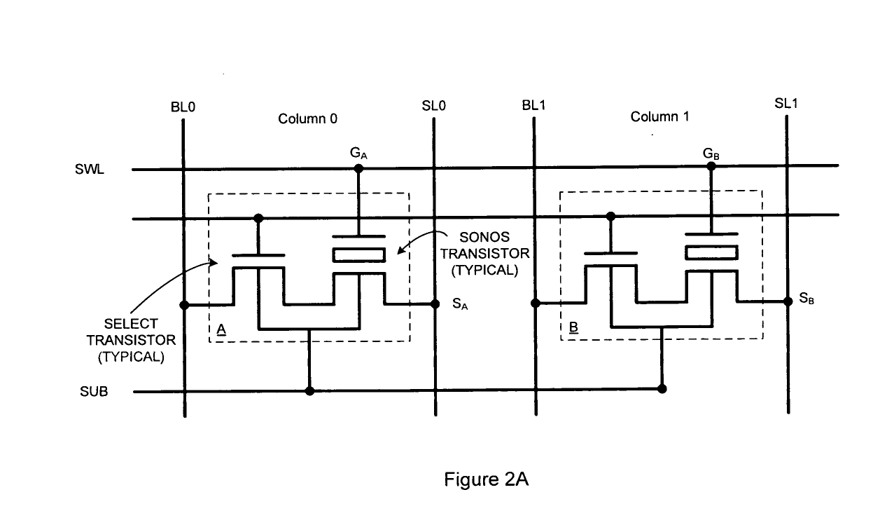

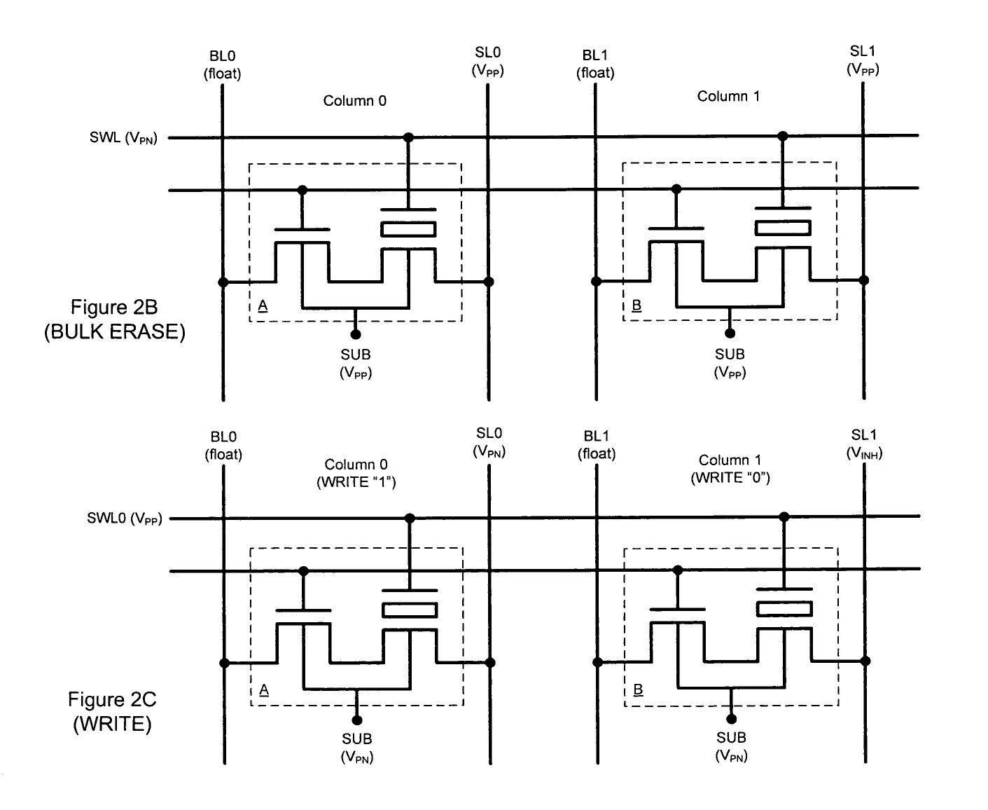

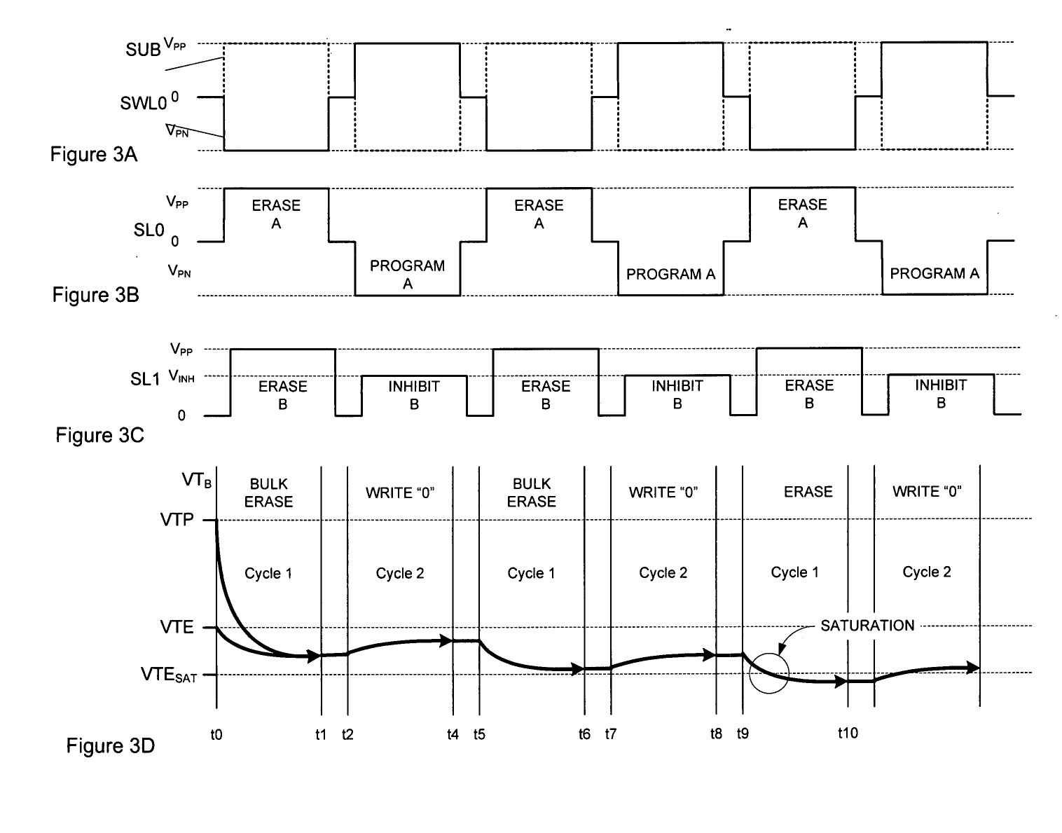

### DETAILED DESCRIPTION

A method and apparatus for eliminating over0erase in a SONOS-type memory is described herein. In the following description, numerous specific details are set forth such as examples of specific components, devices, methods, etc., in order to provide a thorough understanding of embodiments of the present invention. It will be apparent, however, to one skilled in the art that these specific details need not be employed to practice embodiments of the present invention. In other instances, well-known materials or methods have not been described in detail in order to avoid unnecessarily obscuring embodiments of the present invention.

Embodiments of the present invention are described herein using SONOS memory devices as examples of non-volatile trapped-charge memory devices for ease of description. However, embodiments of the invention are not so limited and may include any type of non-volatile, trapped-charge device.

In one embodiment, a method for eliminating over-erase in a SONOS-type memory includes bulk programming a plurality of memory cells in a memory array, bulk erasing the plurality of memory cells and selectively inhibiting one or more memory cells in the plurality of memory cells while applying a programming voltage to the plurality of memory cells.

In one embodiment, a method for preventing over-erase in a memory array comprising rows and columns of memory cells includes: selecting a row of memory cells for a write operation, where the row includes a memory cell, in a first column, to be inhibited from programming and a targeted memory cell, in a second column, to be programmed; applying a first instance of a programming voltage on a word line shared by the targeted memory cell and the memory cell to be inhibited; applying an erase voltage on the word line; and applying an inhibit voltage on a first bit line connected to the cell to be inhibited while applying a second instance of the programming voltage on the word line.

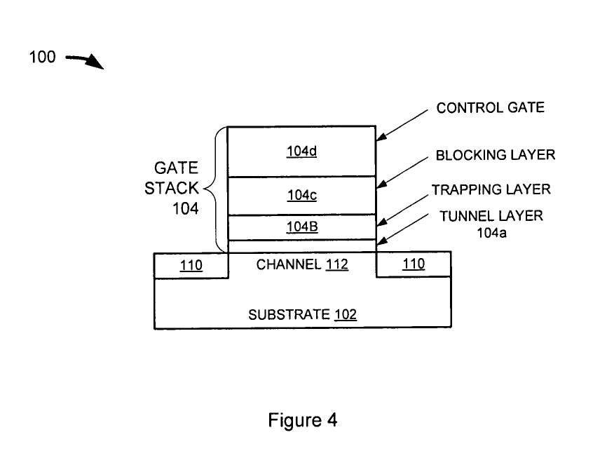

FIG. 4 illustrates one embodiment of a non-volatile trapped-charge semiconductor device 100. Semiconductor device 100 includes a gate stack 104 formed over a substrate 102. Semiconductor device 100 further includes source/drain regions 110 in substrate 102 on either side of gate stack 104, which define a channel region 112 in substrate 102 underneath gate stack 104. Gate stack 104 includes a tunnel dielectric layer 104A, a charge-trapping layer 104B, a top dielectric layer 104C and a gate layer 104D. Gate layer 104D is electrically isolated from substrate 102 by the intervening dielectric layers.

Semiconductor device 100 may be any nonvolatile trapped-charge memory device. In accordance with one embodiment of the present invention, semiconductor device 100 is a SONOS-type device wherein the charge-trapping layer is an insulating dielectric layer having a concentration of charge-trapping sites. By convention, SONOS stands for “Semiconductor-Oxide-Nitride-Oxide-Semiconductor,” where the first “Semiconductor” refers to the gate layer, the first “Oxide” refers to the top dielectric layer (also known as a blocking dielectric layer), “Nitride” refers to the charge-trapping dielectric layer, the second “Oxide” refers to the tunnel dielectric layer and the second “Semiconductor” refers to the channel region material. A SONOS-type device, however, is not limited to these specific materials.

Substrate 102 and, hence, channel region 112, may be any material suitable for semiconductor device fabrication. In one embodiment, substrate 102 may be a bulk substrate of a single crystal of a material which may include, but is not limited to, silicon, germanium, silicon/germanium or a III-V compound semiconductor material. In another embodiment, substrate 102 may be a bulk layer with a top epitaxial layer. In a specific embodiment, the bulk layer may be a single crystal of a material which may include, but is not limited to, silicon, germanium, silicon/germanium, a III-V compound semiconductor material and quartz, while the top epitaxial layer may be a single crystal layer which may include, but is not limited to, silicon, germanium, silicon/germanium and a III-V compound semiconductor material. In another embodiment, substrate 102 may be a top epitaxial layer on a middle insulator layer which is above a lower bulk layer. The top epitaxial layer may be a single crystal layer which may include, but is not limited to, silicon (e.g., to form a silicon-on-insulator semiconductor substrate), germanium, silicon/germanium and a III-V compound semiconductor material. The insulator layer may include, but is not limited to, silicon dioxide, silicon nitride and silicon oxy-nitride. The lower bulk layer may be a single crystal which may include, but is not limited to, silicon, germanium, silicon/germanium, a III-V compound semiconductor material and quartz. Substrate 102 and, hence, channel region 112, may include dopant impurity atoms. In a specific embodiment, channel region 112 is doped P-type and, in an alternative embodiment, channel region 112 is doped N-type.

Source/drain regions 110 in substrate 102 may be any regions having opposite conductivity to channel region 112. For example, in accordance with an embodiment of the present invention, source/drain regions 110 are N-type doped regions while channel region 112 is a P-type doped region. In one embodiment, substrate 102 and, hence, channel region 112, may be boron-doped single-crystal silicon having a boron concentration in the range of 10¹⁵-10¹⁹ atoms/cm³. Source/drain regions 110 may be phosphorous-doped or arsenic-doped regions having a concentration of N-type dopants in the range of 5×10¹⁶-5×10¹⁹ atoms/cm³. In a specific embodiment, source/drain regions 110 may have a depth in substrate 102 in the range of 80-200 nanometers. In accordance with an alternative embodiment of the present invention, source/drain regions 110 are P-type doped regions while channel region 112 is an N-type doped region.

Tunnel dielectric layer 104A may be any material and have any thickness suitable to allow charge carriers to tunnel into the charge-trapping layer under an applied gate bias while maintaining a suitable barrier to leakage when the device is unbiased. In one embodiment, tunnel dielectric layer 104A may be a silicon dioxide or silicon oxy-nitride layer formed by a thermal oxidation process. In another embodiment, tunnel dielectric layer 104A may be a high dielectric constant (high-k) material formed by chemical vapor deposition or atomic layer deposition and may include, but is not limited to, hafnium oxide, zirconium oxide, hafnium silicate, hafnium oxy-nitride, hafnium zirconium oxide and lanthanum oxide. In a specific embodiment, tunnel dielectric layer 104A may have a thickness in the range of 1-10 nanometers. In a particular embodiment, tunnel dielectric layer 104A may have a thickness of approximately 2 nanometers.

Charge-trapping layer 104B may be any material and have any thickness suitable to store charge and, hence, raise the threshold voltage of gate stack 104. In one embodiment, charge-trapping layer 104B may be a dielectric material formed by a chemical vapor deposition process and may include, but is not limited to, stoichiometric silicon nitride, silicon-rich silicon nitride and silicon oxy-nitride. In one embodiment, the thickness of charge-trapping layer 104B may be in the range of 5-10 nanometers.

Top dielectric layer 104C may be any material and have any thickness suitable to maintain a barrier to charge leakage and tunneling under an applied gate bias. In one embodiment, top dielectric layer 104C is formed by a chemical vapor deposition process and is comprised of silicon dioxide or silicon oxy-nitride. In another embodiment, top dielectric layer 104C may be a high-k dielectric material formed by atomic layer deposition and may include, but is not limited to, hafnium oxide, zirconium oxide, hafnium silicate, hafnium oxy-nitride, hafnium zirconium oxide and lanthanum oxide. In a specific embodiment, top dielectric layer 104C may have a thickness in the range of 1-20 nanometers.

Gate layer 104D may be any conductor or semiconductor material suitable for accommodating a bias voltage during operation of the SONOS-type device. In accordance with an embodiment of the present invention, gate layer 104D may be doped poly-crystalline silicon formed by a chemical vapor deposition process. In another embodiment, gate layer 104D may be a metal-containing material formed by physical vapor deposition and may include, but is not limited to, metal nitrides, metal carbides, metal silicides, hafnium, zirconium, titanium, tantalum, aluminum, ruthenium, palladium, platinum, cobalt and nickel.

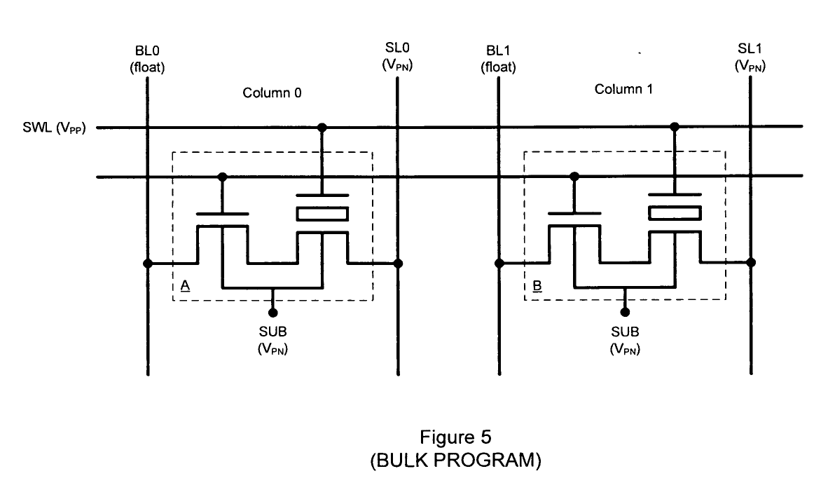

One embodiment of the present invention includes a three cycle write-sequence for writing to SONOS memory. The first cycle is a bulk program (BP) operation, where every cell is programmed to a “1” state. The second cycle is a bulk erase (BE) operation, where every cell is erased to a “0” state. The third cycle is a write operation, where each cell is either programmed or inhibited, as determined by the state of its source-line. FIG. 5 illustrates the voltages for a bulk program operation. As illustrated in FIG. 5, the negative pulse voltage V_{PN} is applied to the common substrate connection SUB and to SL0 and SL1. The positive pulse voltage V_{PP} is applied to the SONOS word line SWL.

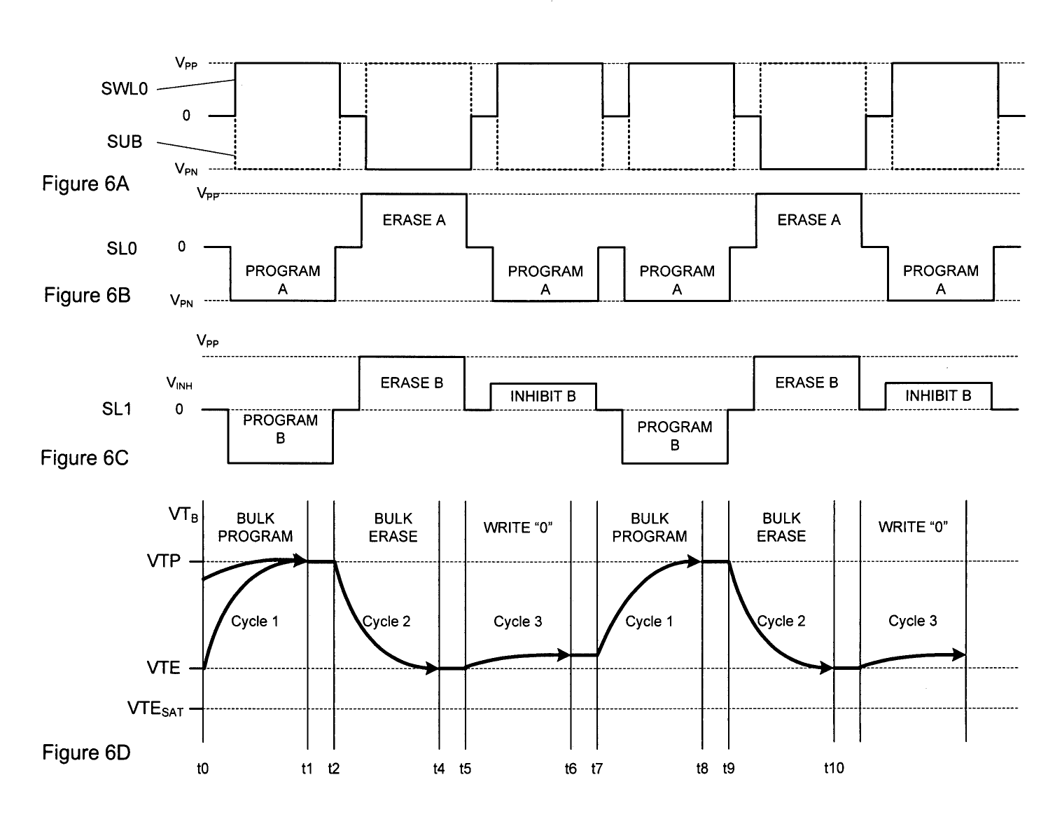

In one embodiment, the SONOS-type transistors in cell A and cell B may be N-type SONOS-type cells, V_{PN} may be approximately −4 volts and V_{PP} may be approximately +6 volts. In another embodiment, the SONOS-type transistors in cell A and cell B may be P-type SONOS-type cells, V_{PN} may be approximately +4 volts and V_{PP} may be approximately −6 volts. FIGS. 6A-C illustrate 3-cycle control voltage waveforms in one embodiment. FIG. 6A illustrates the voltage waveforms on SWL and SUB. FIG. 6B illustrates the voltage waveforms on source line SL0 and FIG. 6C illustrates the voltage waveforms on source line SL1. FIG. 6D illustrates the threshold voltage on the SONOS transistor in cell B (VT_{B}) that results from sequential 3-cycle write operation where cell B is written to a “0.” From t0 to t1 (cycle 1), the bulk program operation programs the SONOS transistor in cell B from either a previous programmed state or erased state. From t2 to t3 (cycle 2), the bulk erase operation transitions the threshold voltage to an erased state. From t4 to t5 (cycle 3), the SONOS transistor in cell B is inhibited from programming and its threshold voltage is slightly increased.

In the next write cycle, from t6 to t11, the sequence is repeated. From t6 to t7 (cycle 1), the bulk program operation programs the SONOS transistor in cell B from its previously erased state. From t8 to t9 (cycle 2), the bulk erase operation transitions the threshold voltage to an erased state. From t10 to t11 (cycle 3), the SONOS transistor in cell B is inhibited from programming and its threshold voltage is slightly increased.

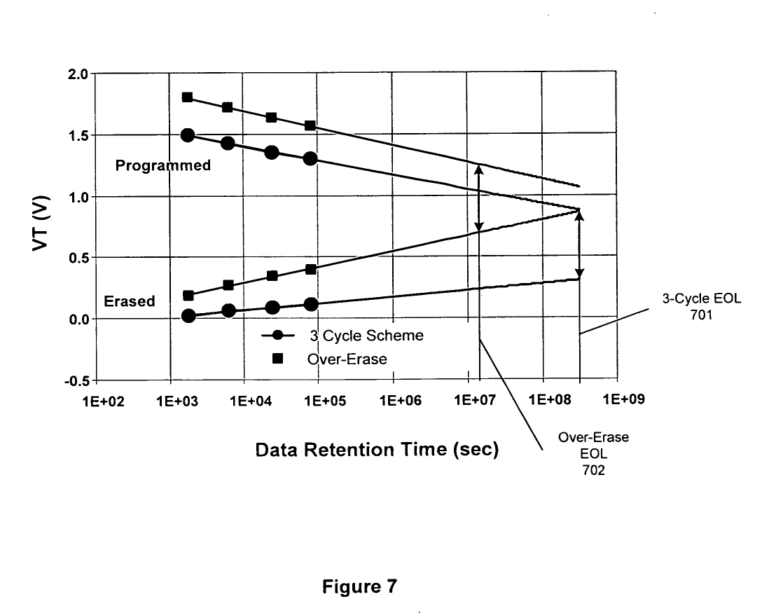

It can be seen that this sequence can be repeated indefinitely without exposing cell B to more than one erase cycle without an intervening programming cycle. As a result, the SONOS transistor in cell B will never be over-erased. The improvement in data retention from 3-cycle programming is illustrated in FIG. 7, which compares the data retention of a SONOS transistor after 1 million cycles of 2-cycle write “0” programming with the data retention of a SONOS transistor after 1 million cycles of 3-cycle write “0” programming. As illustrated in FIG. 7, for the same end of life separation between the programmed threshold voltage and the erased threshold voltage, the EOL using the 3-cycle method (701) is more than an order of magnitude greater than the EOL using the conventional 2-cycle method (702).

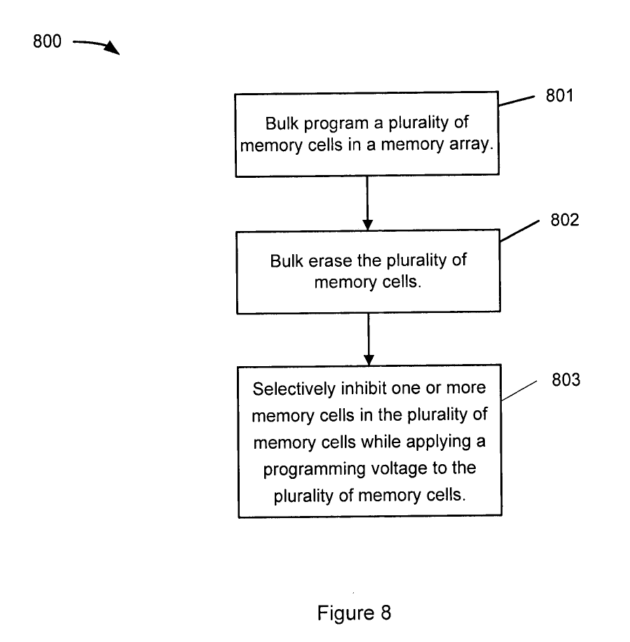

FIG. 8 is a flowchart illustrating one embodiment of a 3-cycle programming method for eliminating over-erase in a SONOS-type memory array having a plurality of SONO-type memory cells. In operation 701, the plurality of memory cells is bulk programmed. In operation 702, the plurality of memory cells is bulk erased. And, in operation 703, one or more of the plurality of memory cells are selectively inhibited from programming while applying a programming voltage to the plurality of memory cells.

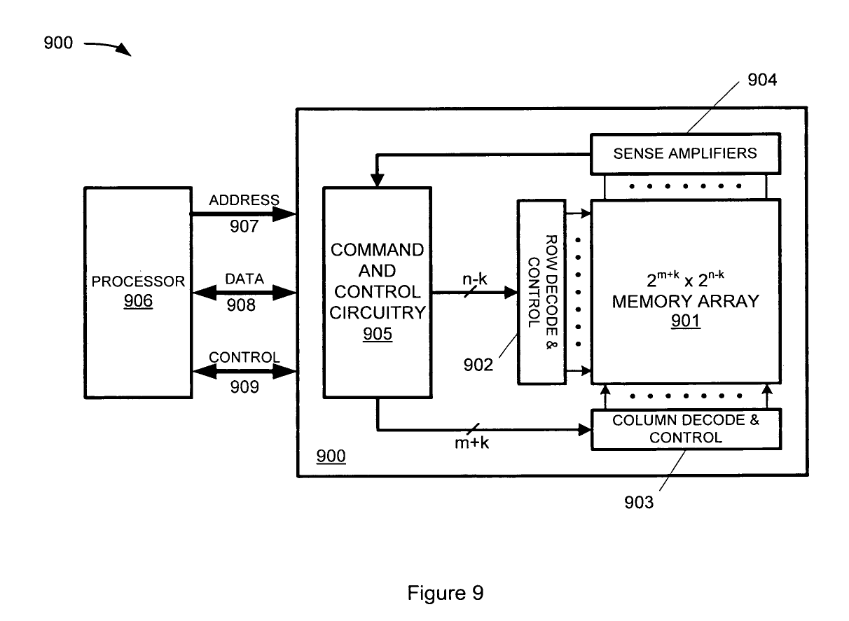

FIG. 9 is a block diagram of processing system 900 including a SONOS-type memory 900 according to one embodiment of the invention. In FIG. 9, the SONOS-type memory 900 includes a SONOS-type memory array 901, which may be an organized as rows and columns of SONOS-type memory cells as described above. In one embodiment, memory array 901 may be an array of 2^{m+k} columns by 2^{n-k} rows of memory cells where k is the length of a data word in bits. Memory array 901 may be coupled to a row decoder and controller 902 via 2^{n-k} word lines (such as SONOS word line SWL) 902A. Memory array 901 may also be coupled to a column decoder and controller 902 via 2^{m+k} source lines (such as source lines SL0 and SL1) 903A. Row and column decoders and controllers are known in the art and, accordingly, are not described in detail herein. Memory array 901 may also be coupled to a plurality of sense amplifiers 904 as are known in the art to read k-bit words from memory array 901. Memory 900 may also include command and control circuitry 905, as is known in the art, to control row decoder and controller 902, column decoder and controller 903 and sense amplifiers 904, and also to receive read data from sense amplifiers 904.

Memory 900 may also be coupled to a processor 906 in a conventional manner via an address bus 907, a data bus 908 and a control bus 909. Processor 906 may be any type of general purpose or special purpose processing device, for example.

Although the present invention has been described with reference to specific exemplary embodiments, it will be evident that various modifications and changes may be made to these embodiments without departing from the broader spirit and scope of the invention as set forth in the claims. Accordingly, the specification and drawings are to be regarded in an illustrative rather than a restrictive sense.

What is claimed is:

1. A method, comprising:
bulk programming a plurality of memory cells in a memory array;
bulk erasing the plurality of memory cells; and
selectively inhibiting one or more memory cells in the plurality of memory cells while applying a programming voltage to the plurality of memory cells.

2. The method of claim 1, wherein the plurality of memory cells comprises a plurality of non-volatile, trapped-charge memory devices.

3. The method of claim 2, wherein the plurality of non-volatile trapped-charge memory devices comprises a plurality of SONOS-type devices.

4. The method of claim 1, wherein each of the plurality of memory cells comprises a SONOS-type device coupled to a select transistor.

5. The method of claim 3, wherein each of the plurality of SONOS-type devices comprises one of an n-type SONOS-type device and a p-type SONOS-type device.

6. A method for preventing over-erase in a memory array comprising rows and columns of memory cells, the method comprising:
selecting a row of memory cells for a write operation, the row comprising a memory cell, in a first column, to be inhibited from programming and a targeted memory cell, in a second column, to be programmed;
applying a first instance of a programming voltage on a word line shared by the targeted memory cell and the memory cell to be inhibited;
applying an erase voltage on the word line; and
applying an inhibit voltage on a first bit line connected to the cell to be inhibited while applying a second instance of the programming voltage on the word line.

7. The method of claim 6, wherein the first column includes the first bit line and a first source line coupled to the memory cell to be inhibited and the second column includes a second bit line and a second source line coupled to the targeted cell.

8. The method of claim 7, wherein the memory cell to be inhibited includes a trapped-charge memory transistor and a field effect select transistor, the memory transistor having a drain connected to the first bit line, a control gate connected to the word line, a source connected to a drain of the select transistor and a body connected to a reference potential, the select transistor having a control gate connected to a select line and a source connected to the first source line.

9. The method of claim 7, wherein the targeted memory cell includes a trapped-charge memory transistor and a field effect select transistor, the memory transistor having a drain connected to the second bit line, a control gate connected to the word line, a source connected to a drain of the select transistor and a body connected to a reference potential, the select transistor having a control gate connected to a select line and a source connected to the second source line.

10. The method of claim 8, wherein the memory transistor comprises an n-type SONOS-type transistor, wherein the programming voltage is approximately +10 volts with respect to the reference potential, the erase voltage is approximately −10 volts with respect to the reference potential and the inhibit voltage is approximately +6 volts with respect to the reference potential.

11. The method of claim 8, wherein the memory transistor comprises a p-type SONOS-type transistor, wherein the programming voltage is approximately −10 volts with respect to the reference potential, the erase voltage is approximately +10 volts with respect to the reference potential and the inhibit voltage is approximately −6 volts with respect to the reference potential.

12. A memory device, comprising:
a memory array comprising memory cells arranged in rows and columns;
a memory controller coupled to the memory array, comprising:
a row controller configured to select a row of the memory array for a write operation, wherein the row comprises a memory cell to be inhibited from programming, in a first column, and a targeted memory cell to be programmed in a second column, wherein the row controller is configured to:
apply a first instance of a programming voltage on a word line shared by the targeted memory cell and the memory cell to be inhibited; and
apply an erase voltage on the word line; and
a column controller configured to apply an inhibit voltage to the memory cell to be inhibited, wherein the row controller is further configured to apply a second instance of the programming voltage on the word line.

13. The memory device of claim 12, wherein the first column includes a first bit line and a first source line coupled to the memory cell to be inhibited and the second column includes a second bit line and a second source line coupled to the targeted cell.

14. The memory device of claim 13, wherein the memory cell to be inhibited includes a trapped-charge memory transistor and a field effect select transistor, the memory transistor having a drain connected to the first bit line, a control gate connected to the word line, a source connected to a drain of the select transistor and a body connected to a reference potential, the select transistor having a control gate connected to a select line and a source connected to the first source line.

15. The memory device of claim 13, wherein the targeted memory cell includes a trapped-charge memory transistor and a field effect select transistor, the memory transistor having a drain connected to the second bit line, a control gate connected to the word line, a source connected to a drain of the select transistor and a body connected to a reference potential, the select transistor having a control gate connected to a select line and a source connected to the second source line.

16. The memory device of claim 14, wherein the memory transistor comprises an n-type SONOS-type transistor, wherein the programming voltage is approximately +10 volts with respect to the reference potential, the erase voltage is approximately −10 volts with respect to the reference potential and the inhibit voltage is approximately +6 volts with respect to the reference potential.

17. The memory device of claim 14, wherein the memory transistor comprises a p-type SONOS-type transistor, wherein the programming voltage is approximately −10 volts with respect to the reference potential, the erase voltage is approximately +10 volts with respect to the reference potential and the inhibit voltage is approximately −6 volts with respect to the reference potential.

18. An apparatus, comprising:
means for controlling a memory array; and
means for preventing over-erase in a memory cell in the memory array during a write operation.

19. The apparatus of claim 18, wherein the means for preventing over-erase comprises means for limiting sequential erase operations to a maximum of one.

20. The apparatus of claim 18, wherein the means for preventing over-erase comprises:
means for bulk programming a plurality of selected memory cells in a memory array;
means for bulk erasing the plurality of selected memory cells; and
means for selectively inhibiting one or more memory cells in the plurality of memory cells while applying a programming voltage to the plurality of memory cells.
